(19) United States
(12) Patent Application Publication
(10) Pub. No.: US 2025/0392063 A1
(43) Pub. Date: Dec. 25, 2025

(54) CABLE CONNECTOR ASSEMBLY WITH IMPROVED STRUCTURAL RELIABILITY AND METHOD OF MANUFACTURING THE SAME

(71) Applicant: DONGGUAN LUXSHARE TECHNOLOGIES CO., LTD, Dongguan City (CN)

(72) Inventor: Kunlin YAO, Dongguan City (CN)

(73) Assignee: DONGGUAN LUXSHARE TECHNOLOGIES CO., LTD, Dongguan City, Guangdong Province (CN)

(21) Appl. No.: 18/887,140

(22) Filed: Sep. 17, 2024

(30) Foreign Application Priority Data
Jun. 19, 2024 (CN) 202410796613.4

(51) Int. Cl. H01R 12/51; H01R 12/70; H01R 12/75; H01R 13/02; H01R 43/20; H01R 43/24

(52) U.S. Cl. CPC H01R 12/515; H01R 12/7047; H01R 12/7052; H01R 12/75; H01R 13/025; H01R 43/205; H01R 43/24

(57) ABSTRACT

A cable connector assembly includes an electrical connector, a circuit board and a cable module. The electrical connector includes a body portion and a number of conductive terminals. At least part of the conductive terminals includes a contact portion and a mounting portion. The electrical connector is mounted with the circuit board. The cable module includes a number of cables and a fixing block fixing the cables. The cable includes a core. The fixing block is secured to the circuit board so that the core of the cable corresponds to the mounting portion of a corresponding conductive terminal. The core of the cable is electrically connected to the mounting portion of the corresponding conductive terminal. A method of manufacturing the cable connector assembly is also disclosed.

### CROSS-REFERENCE TO RELATED APPLICATION

This patent application claims priority of a Chinese Patent Application No. 202410796613.4, filed on Jun. 19, 2024 and titled “CABLE CONNECTOR ASSEMBLY AND METHOD OF MANUFACTURING THE SAME”, the entire content of which is incorporated herein by reference.

### TECHNICAL FIELD

The present disclosure relates to a cable connector assembly and a method of manufacturing the same, which belongs to the technical field of connectors.

### BACKGROUND

A cable connector assembly in the related art includes an electrical connector, a circuit board and a plurality of cables. The electrical connector includes a body portion and a plurality of conductive terminals. The conductive terminal includes a contact portion and a mounting portion. The plurality of cables are usually connected to the electrical connector first, and then the electrical connector is mounted to the circuit board. The cable includes a core. The core of the cable and the mounting portion of the conductive terminal are electrically connected through soldering or welding.

After soldering or welding, the cables in the related art are easily pulled by external forces, causing the soldering or welding between the core of the cable and the mounting portion of the conductive terminal to loosen or even fall off.

Therefore, it is desirable to improve the cable connector assembly and its manufacturing method in the related art.

### SUMMARY

An object of the present disclosure is to provide a cable connector assembly with better structural reliability and a method of manufacturing the same.

In order to achieve the above object, the present disclosure adopts the following technical solution: a cable connector assembly, including: an electrical connector, the electrical connector including a body portion and a plurality of conductive terminals provided on the body portion; at least part of the conductive terminals including a contact portion and a mounting portion; the contact portion being configured to be in contact with a mating module; a circuit board, the electrical connector and the circuit board being mounted together; and a cable module, the cable module including a plurality of cables and a fixing block fixing the plurality of cables; the cable including a core; the fixing block being secured to the circuit board so that the core of the cable corresponds to the mounting portion of a corresponding conductive terminal; the core of the cable being electrically connected to the mounting portion of the corresponding conductive terminal.

In order to achieve the above object, the present disclosure adopts the following technical solution: a method of manufacturing a cable connector assembly, the cable connector assembly including: an electrical connector, the electrical connector including a body portion and a plurality of conductive terminals provided on the body portion; at least part of the conductive terminals including a contact portion and a mounting portion; the contact portion being configured to be in contact with a mating module; a circuit board, the electrical connector and the circuit board being mounted together; and a cable module, the cable module including a plurality of cables and a fixing block fixing the plurality of cables; the cable including a core; the fixing block being secured to the circuit board so that the core of the cable corresponds to the mounting portion of a corresponding conductive terminal; the core of the cable being electrically connected to the mounting portion of the corresponding conductive terminal; the method including: providing the electrical connector; providing the circuit board, and mounting the electrical connector and the circuit board together; providing the cable module, and securing the fixing block to the circuit board so that the core of the cable corresponds to the mounting portion of the corresponding conductive terminal.

Compared with the prior art, the cable module of the present disclosure is integrally mounted to the electrical connector. By securing the fixing block to the circuit board, the core of the cable can be made to correspond to the mounting portion of the corresponding conductive terminal. The core of the cable is electrically connected to the mounting portion of the corresponding conductive terminal. Therefore, the cable connector assembly and the method of manufacturing the same as disclosed by the present disclosure improve structural reliability and assembly efficiency.

### BRIEF DESCRIPTION OF DRAWINGS

FIG. 1 is a perspective schematic view of a cable connector assembly in accordance with an embodiment of the present disclosure;

FIG. 2 is a perspective view of FIG. 1 from another angle;

FIG. 3 is a schematic perspective view of FIG. 1 from another angle;

FIG. 4 is a top view of FIG. 1;

FIG. 5 is a top view of FIG. 2;

FIG. 6 is a front view of FIG. 1;

FIG. 7 is a partially exploded perspective view of FIG. 3;

FIG. 8 is a partially exploded perspective view of FIG. 1;

FIG. 9 is a partial enlarged view of a circled portion B in FIG. 8;

FIG. 10 is a partial enlarged view of a circled portion C in FIG. 8;

FIG. 11 is a partially exploded perspective view of FIG. 2;

FIG. 12 is a partial enlarged view of a circled portion D in FIG. 11;

FIG. 13 is a partial enlarged view of a circled portion E in FIG. 11;

FIG. 14 is a perspective schematic view of a circuit board in FIG. 1;

FIG. 15 is a perspective view of FIG. 14 from another angle;

FIG. 16 is a perspective view of an electrical connector in FIG. 1;

FIG. 17 is a partially exploded perspective view of FIG. 16;

FIG. 18 is a schematic perspective view of a body portion in FIG. 17 from another angle;

FIG. 19 is an exploded perspective view of a first cable module and a second cable module in FIG. 8 in a first embodiment;

FIG. 20 is an exploded perspective view of FIG. 19 from another angle;

FIG. 21 is an exploded perspective view of the first cable module and the second cable module in FIG. 8 in a second embodiment;

FIG. 22 is an exploded perspective view of FIG. 21 from another angle;

FIG. 23 is a partially exploded perspective view of a hybrid terminal module in FIG. 17;

FIG. 24 is a partially exploded perspective view of FIG. 23 from another angle;

FIG. 25 is a schematic cross-sectional view taken along line F-F in FIG. 4;

FIG. 26 is a schematic cross-sectional view taken along line G-G in FIG. 4; and

FIG. 27 is a schematic cross-sectional view taken along line H-H in FIG. 4.

### DETAILED DESCRIPTION

Exemplary embodiments will be described in detail here, examples of which are shown in drawings. When referring to the drawings below, unless otherwise indicated, same numerals in different drawings represent the same or similar elements. The examples described in the following exemplary embodiments do not represent all embodiments consistent with this application. Rather, they are merely examples of devices and methods consistent with some aspects of the application as detailed in the appended claims.

The terminology used in this application is only for the purpose of describing particular embodiments, and is not intended to limit this application. The singular forms “a”, “said”, and “the” used in this application and the appended claims are also intended to include plural forms unless the context clearly indicates other meanings.

It should be understood that the terms “first”, “second” and similar words used in the specification and claims of this application do not represent any order, quantity or importance, but are only used to distinguish different components. Similarly, “an” or “a” and other similar words do not mean a quantity limit, but mean that there is at least one; “multiple” or “a plurality of” means two or more than two. Unless otherwise noted, “front”, “rear”, “lower” and/or “upper” and similar words are for ease of description only and are not limited to one location or one spatial orientation. Similar words such as “include” or “comprise” mean that elements or objects appear before “include” or “comprise” cover elements or objects listed after “include” or “comprise” and their equivalents, and do not exclude other elements or objects. The term “a plurality of” mentioned in the present disclosure includes two or more.

Hereinafter, some embodiments of the present disclosure will be described in detail with reference to the accompanying drawings. In the case of no conflict, the following embodiments and features in the embodiments can be combined with each other.

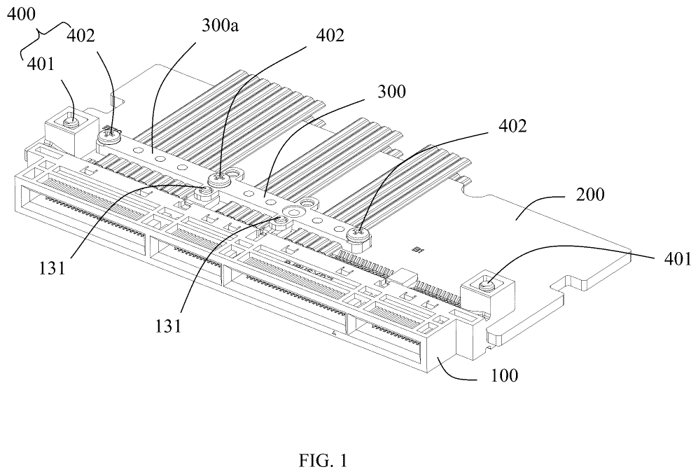

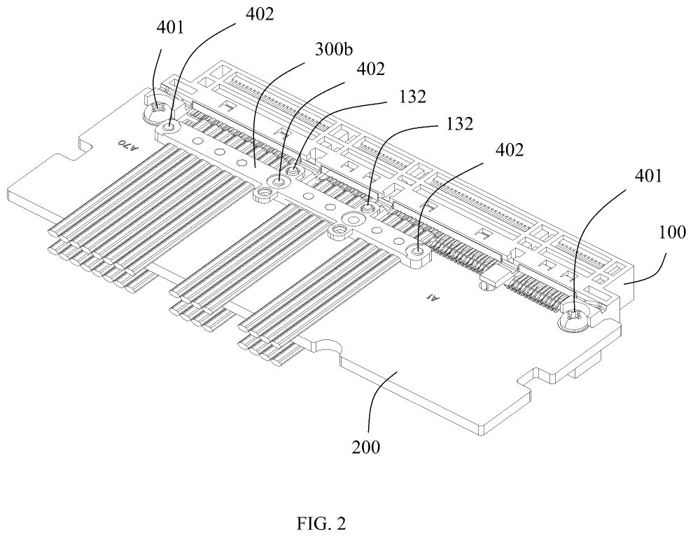

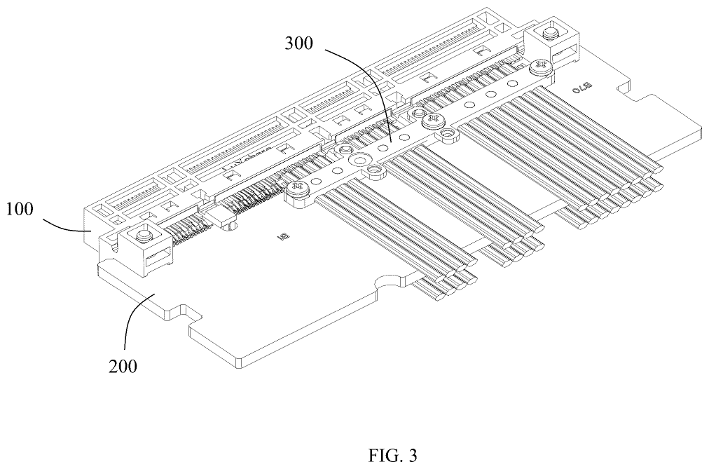

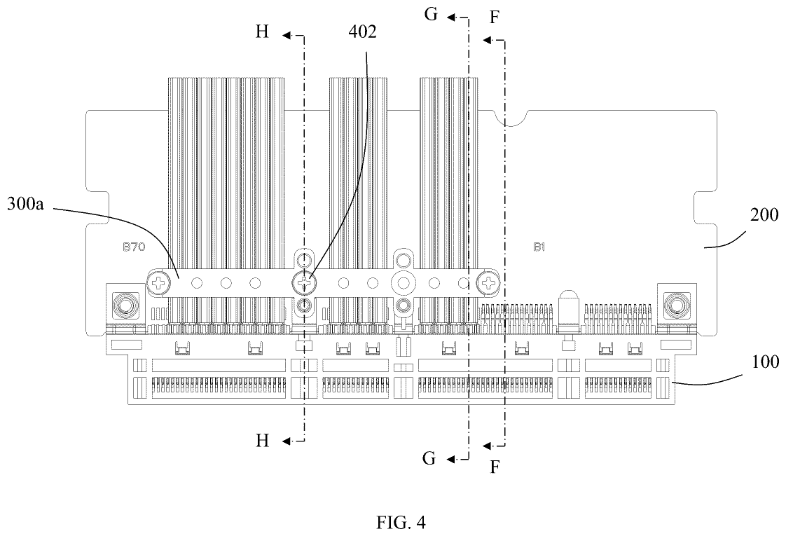

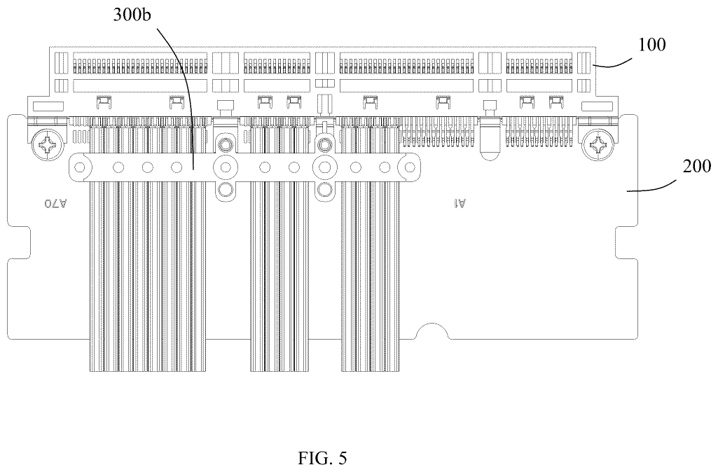

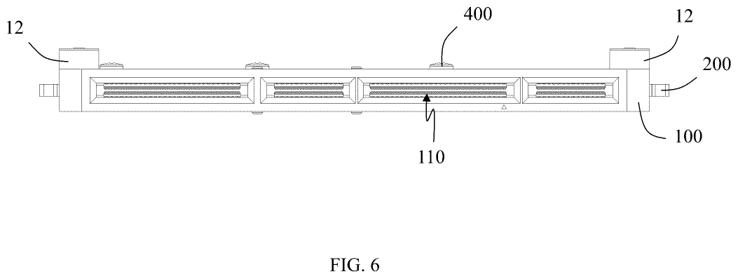

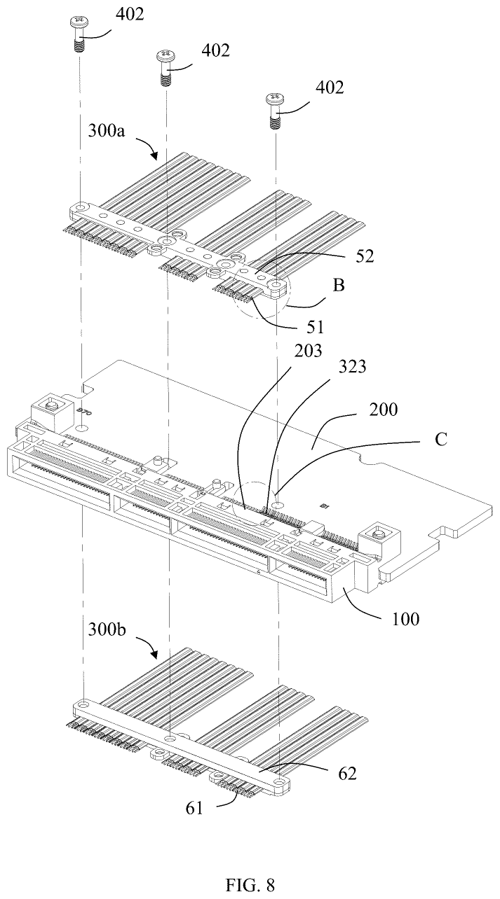

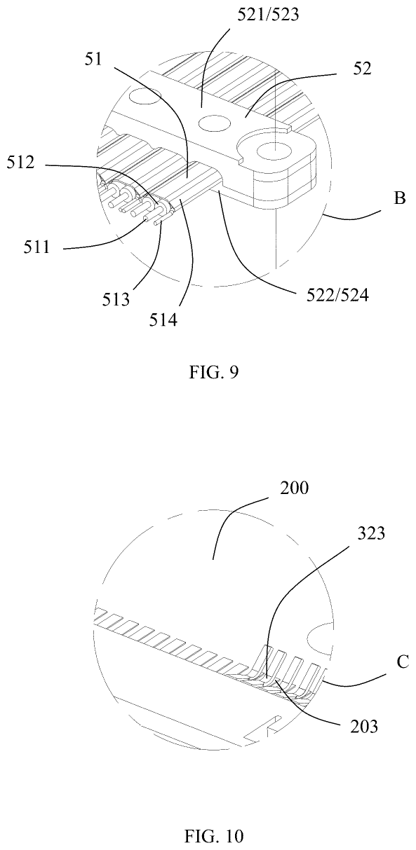

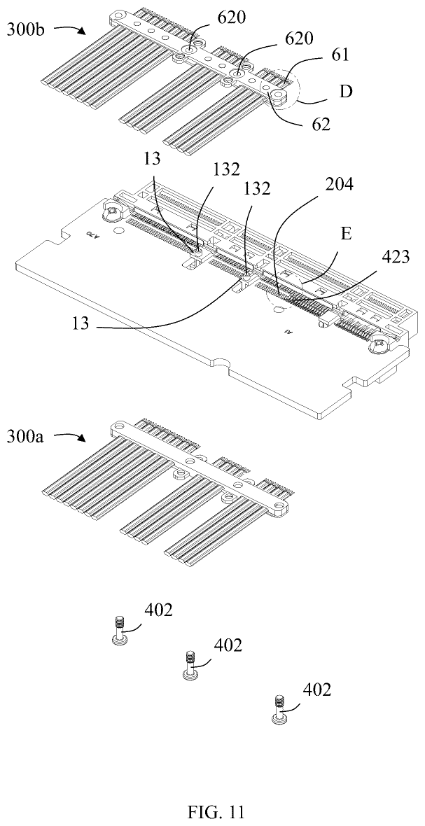

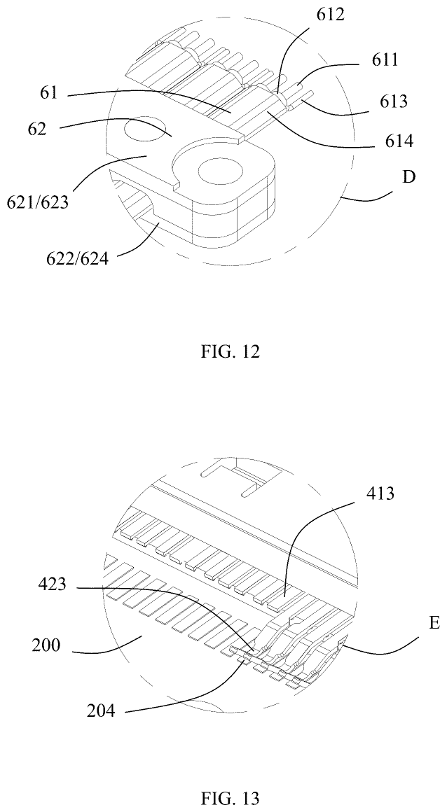

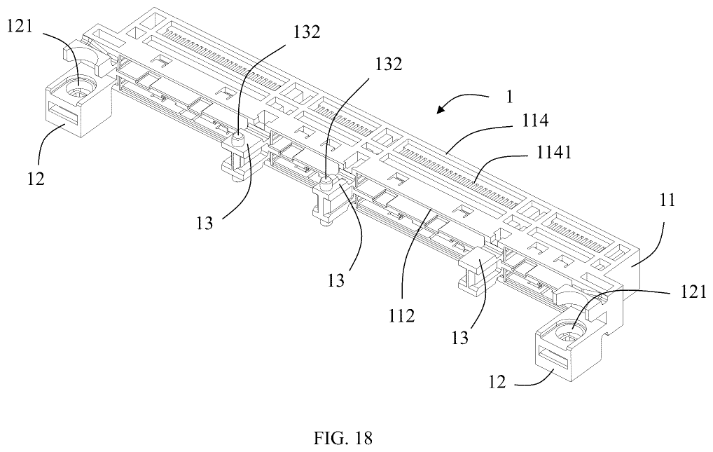

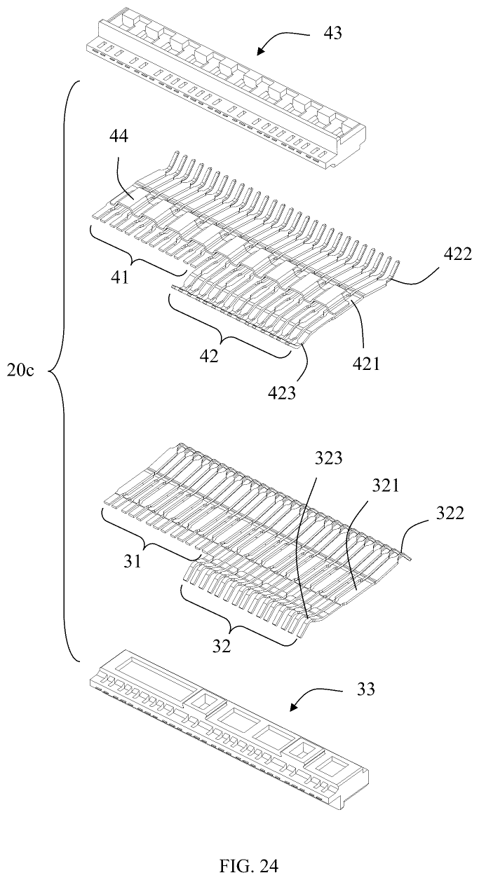

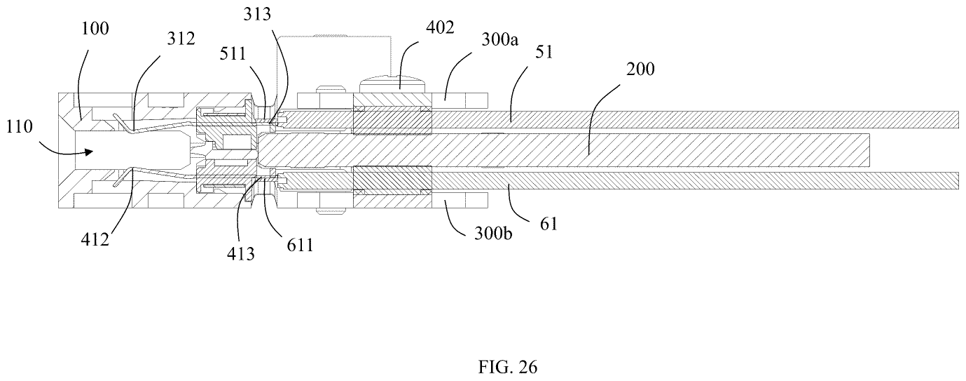

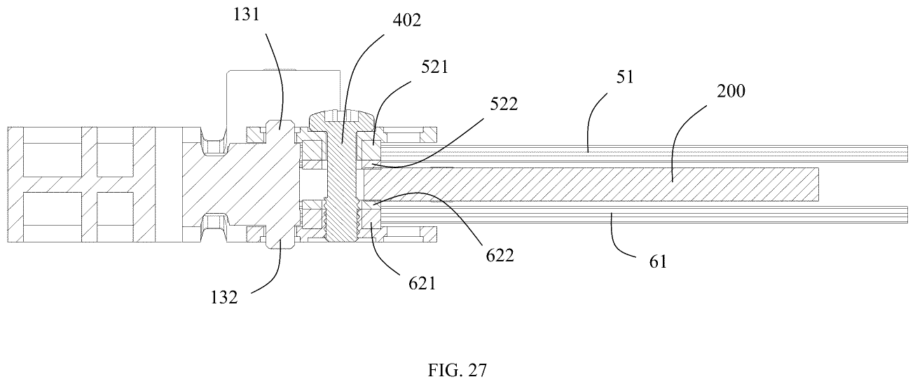

Referring to FIG. 1 to FIG. 27, the present disclosure discloses a cable connector assembly, which includes an electrical connector 100, a circuit board 200, a cable module 300 and a fastening device 400. The electrical connector 100 and the circuit board 200 are assembled together. The fastening device 400 secures the electrical connector 100 and the circuit board 200. Besides, the cable module 300 is assembled with the electrical connector 100 and the circuit board 200. The fastening device 400 also secures the cable module 300, the electrical connector 100 and the circuit board 200.

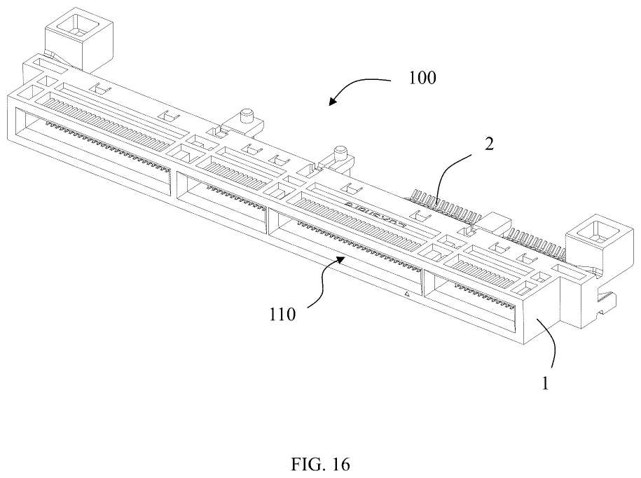

Referring to FIG. 16, in the illustrated embodiment of the present disclosure, the electrical connector 100 includes a body portion 1 and a plurality of conductive terminals 2 provided on the body portion 1. Each conductive terminal 2 includes a contact portion. The contact portion is configured to be in contact with a mating module (not shown) to achieve data transmission. In the illustrated embodiment of the present disclosure, the contact portion has an arc-shaped contact surface which is configured to be in contact with the mating module.

Referring to FIG. 16 to FIG. 18, in the illustrated embodiment of the present disclosure, the body portion 1 is made of insulating material and includes a base portion 11, a plurality of mounting protrusions 12 extending backwardly from two sides of the base portion 11 along a first direction A1-A1 (for example, a front-back direction), and a plurality of extending protrusions 13 extending backwardly from the base portion 11 along the first direction A1-A1. In the illustrated embodiment of the present disclosure, the plurality of extending protrusions 13 are spaced apart along a second direction A2-A2 (for example, a left-right direction).

The base portion 11 includes a mating surface 111, a rear end surface 112 opposite to the mating surface 111, and a mating slot 110 extending through the mating surface 111 along the first direction A1-A1. Besides, the base portion 11 further includes a first wall portion 113 (for example, a top wall) and a second wall portion 114 (for example, a bottom wall) opposite to the first wall portion 113. The mating slot 110 is located between the first wall portion 113 and the second wall portion 114 along a third direction A3-A3 (for example, a top-bottom direction). In the illustrated embodiment of the present disclosure, the first wall portion 113 defines a first hollow groove 1131 extending through the first wall portion 113 along the third direction A3-A3. The first hollow groove 1131 is in communication with the mating slot 110. Similarly, the second wall portion 114 defines a second hollow groove 1141 extending through the second wall portion 114 along the third direction A3-A3. The second hollow groove 1141 is in communication with the mating slot 110. It is understandable to those skilled in the art that the first hollow groove 1131 and the second hollow groove 1141 are capable of at least improving the heat dissipation.

In the illustrated embodiment of the present disclosure, a plurality of mating slots 110 are provided and they are spaced apart along the second direction A2-A2. According to design requirements, widths of the plurality of mating slots 110 along the second direction A2-A2 may be the same or different. In the illustrated embodiment of the present disclosure, the mating slot 110 includes a first mating slot 1101, a second mating slot 1102 and a third mating slot 1103.

Each mounting protrusion 12 includes a mounting hole 121 extending the mounting protrusion 12 along the third direction A3-A3.

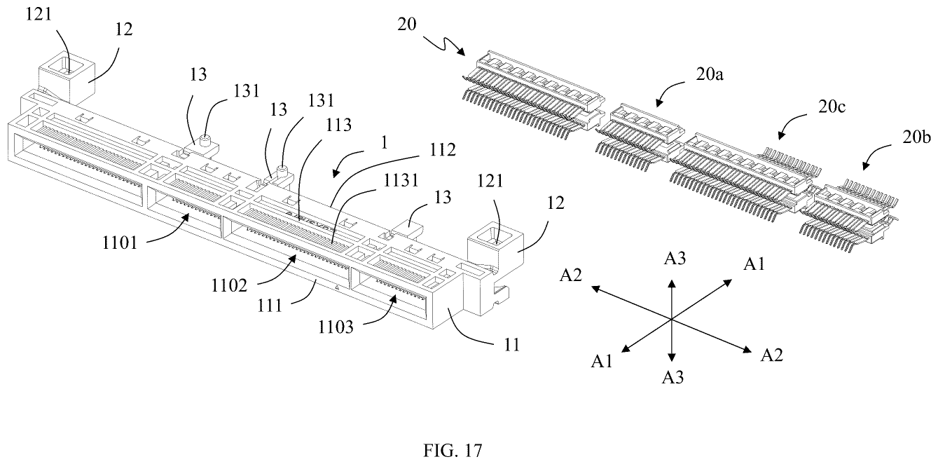

Referring to FIG. 17, in the illustrated embodiment of the present disclosure, the electrical connector 100 includes a plurality of terminal modules 20. The conductive terminals 2 are provided on the body portion 1 in the form of terminal modules 20. Of course, it is understandable to those skilled in the art that the conductive terminals 2 can also be provided on the body portion 1 in other ways. For example, the conductive terminals 2 are directly assembled and fixed to the body portion 1, or the conductive terminals 2 are insert-molded with the body portion 1. The manner in which the conductive terminals 2 are provided on the body portion 1 is well known to those skilled in the art, and will not be described in detail in the present disclosure.

In the illustrated embodiment of the present disclosure, the plurality of terminal modules 20 are divided into three categories: a first category is a cable terminal module 20a, a second category is a board-end terminal module 20b, and a third category is a hybrid terminal module 20c. The cable terminal module 20a corresponds to the first mating slot 1101, the board-end terminal module 20b corresponds to the third mating slot 1103, and the hybrid terminal module 20c corresponds to the second mating slot 1102. In the illustrated embodiment of the present disclosure, the hybrid terminal module 20c is located between the cable terminal module 20a and the board-end terminal module 20b along the second direction A2-A2.

The cable terminal module 20a means that the conductive terminals 2 in the terminal module are configured to be electrically connected to cables. The board-end terminal module 20b means that the conductive terminals 2 in the terminal module are configured to be electrically connected to the circuit board 200. The hybrid terminal module 20c means that part of the conductive terminals 2 in the terminal module are configured to be electrically connected to the cables, and another part of the conductive terminals 2 are configured to be electrically connected to the circuit board 200. Since the hybrid terminal module 20c includes the conductive terminals 2 in the cable terminal module 20a and the board-end terminal module 20b, the following description only takes the hybrid terminal module 20c as an example. It is understandable to those skilled in the art that when the cable terminals in the hybrid terminal module 20c are removed, the terminal module obtained is the board-end terminal module 20b; and when the board-end terminals in the hybrid terminal module 20c are removed, the terminal module obtained is the cable terminal module 20a.

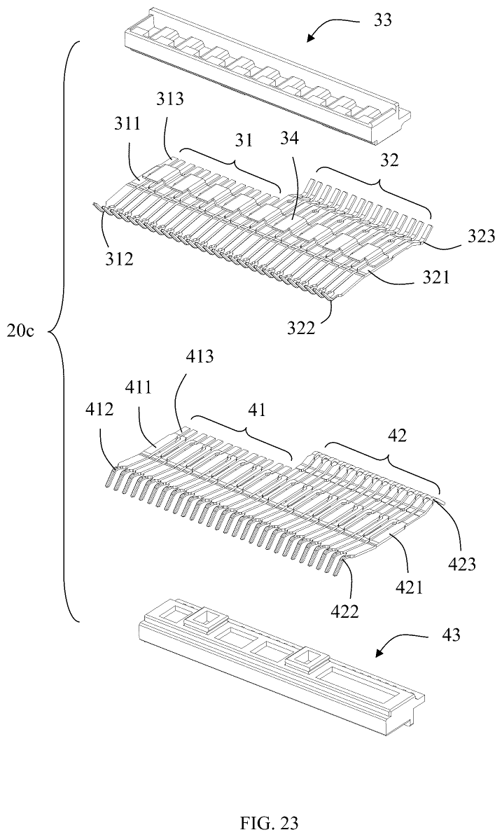

Referring to FIG. 23 to FIG. 26, in the illustrated embodiment of the present disclosure, the hybrid terminal module 20c includes a plurality of first cable terminals 31, a plurality of first board-end terminals 32, a first insulating block 33 and a first grounding plate 34. In the illustrated embodiment of the present disclosure, the plurality of first cable terminals 31 and the plurality of first board-end terminals 32 are disposed along the second direction A2-A2. The plurality of first cable terminals 31 and the plurality of first board-end terminals 32 are fixed to the first insulating block 33. In the illustrated embodiment of the present disclosure, the plurality of first cable terminals 31 and the plurality of first board-end terminals 32 are insert-molded with the first insulating block 33 to be integrated as a whole.

In the illustrated embodiment of the present disclosure, each first cable terminal 31 includes a first fixing portion 311 fixed to the first insulating block 33, a first contact portion 312 extending from one end of the first fixing portion 311 and a first mounting portion 313 extending from another end of the first fixing portion 311. In the illustrated embodiment of the present disclosure, the first contact portion 312 protrudes forwardly beyond the first insulating block 33 in a cantilever shape. The first contact portion 312 protrudes into the mating slot 110 to achieve electrical connection with the mating module through an elastic contact manner. The first contact portion 312 is provided with an arc-shaped contact surface that abuts against the mating module. The first mounting portion 313 is in the shape of a straight strip and protrudes backwardly beyond the rear end surface 112 to be connected to a corresponding cable.

The first board-end terminal 32 includes a first holding portion 321 fixed to the first insulating block 33, a first mating portion 322 extending from one end of the first holding portion 321, and a first tail portion 323 extending from another end of the first holding portion 321. In the illustrated embodiment of the present disclosure, the first mating portion 322 protrudes forwardly beyond the first insulating block 33 in a cantilever shape. The first mating portion 322 protrudes into the mating slot 110 to achieve electrical connection with the mating module through an elastic contact manner. The first mating portion 322 is provided with an arc-shaped contact surface that abuts against the mating module. The first tail portion 323 protrudes backwardly beyond the first insulating block 33 in a cantilever shape. The first tail portion 323 is electrically connected to the circuit board 200 through an elastic contact manner. The first tail portion 323 is provided with an arc-shaped contact surface that abuts against the circuit board 200. In the illustrated embodiment of the present disclosure, the first tail portion 323 extends backwardly and protrudes beyond the first mounting portion 313 along the first direction A1-A1.

In the illustrated embodiment of the present disclosure, both of the plurality of first cable terminals 31 and the plurality of first board-end terminals 32 include a plurality of first signal terminals and a plurality of first ground terminals. The first grounding plate 34 connects all the first ground terminals together in series to improve the quality of signal transmission.

In the illustrated embodiment of the present disclosure, the hybrid terminal module 20c further includes a plurality of second cable terminals 41, a plurality of second board-end terminals 42, a second insulating block 43 and a second grounding plate 44. In the illustrated embodiment of the present disclosure, the plurality of second cable terminals 41 and the plurality of second board-end terminals 42 are disposed along the second direction A2-A2. The plurality of second cable terminals 41 and the plurality of second board-end terminals 42 are fixed to the second insulating block 43. In the illustrated embodiment of the present disclosure, the plurality of second cable terminals 41 and the plurality of second board-end terminals 42 are insert-molded with the second insulating block 43 to be integral as a whole.

In the illustrated embodiment of the present disclosure, each second cable terminal 41 includes a second fixing portion 411 fixed to the second insulating block 43, a second contact portion 412 extending from one end of the second fixing portion 411, and a second mounting portion 413 extending from another end of the second fixing portion 411. In the illustrated embodiment of the present disclosure, the second contact portion 412 protrudes forwardly beyond the second insulating block 43 in a cantilever shape. The second contact portion 412 protrudes into the mating slot 110 to achieve electrical connection with the mating module through an elastic contact manner. The second contact portion 412 is provided with an arc-shaped contact surface that abuts against the mating module. The second mounting portion 413 is in the shape of a straight strip and protrudes backwardly beyond the rear end surface 112 to be connected to a corresponding cable.

The second board-end terminal 42 includes a second holding portion 421 fixed to the second insulating block 43, a second mating portion 422 extending from one end of the second holding portion 421, and a second tail portion 423 extending from another end of the second holding portion 421. In the illustrated embodiment of the present disclosure, the second mating portion 422 protrudes forwardly beyond the second insulating block 43 in a cantilever shape.

The second mating portion 422 protrudes into the mating slot 110 to achieve electrical connection with the mating module through an elastic contact manner. The second mating portion 422 is provided with an arc-shaped contact surface that abuts against the mating module. The second tail portion 423 protrudes backwardly beyond the second insulating block 43 in a cantilever shape. The second tail portion 423 is electrically connected to the circuit board 200 through an elastic contact manner. The second tail portion 423 is provided with an arc-shaped contact surface that abuts against the circuit board 200. In the illustrated embodiment of the present disclosure, the second tail portion 423 extends backwardly and protrudes beyond the second mounting portion 413 along the first direction A1-A1.

In the illustrated embodiment of the present disclosure, both of the plurality of second cable terminals 41 and the plurality of second board-end terminals 42 include a plurality of second signal terminals and a plurality of second ground terminals. The second grounding plate 44 connects all the second ground terminals in series to improve the quality of signal transmission.

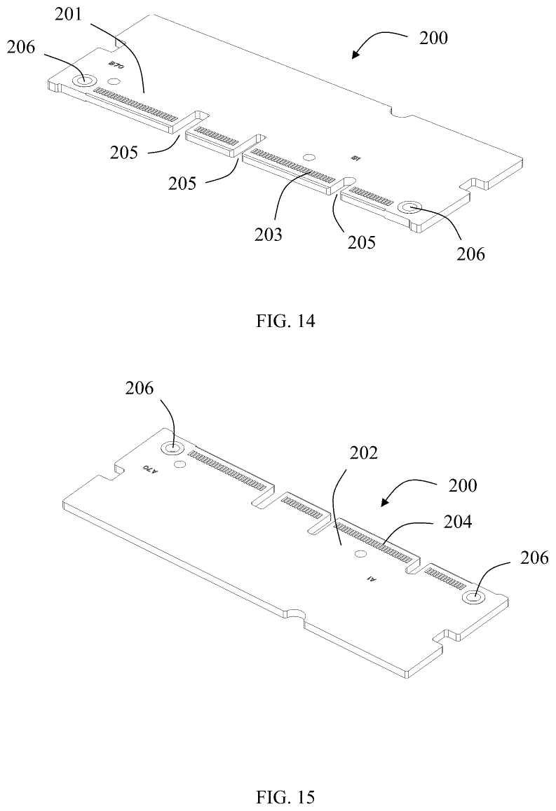

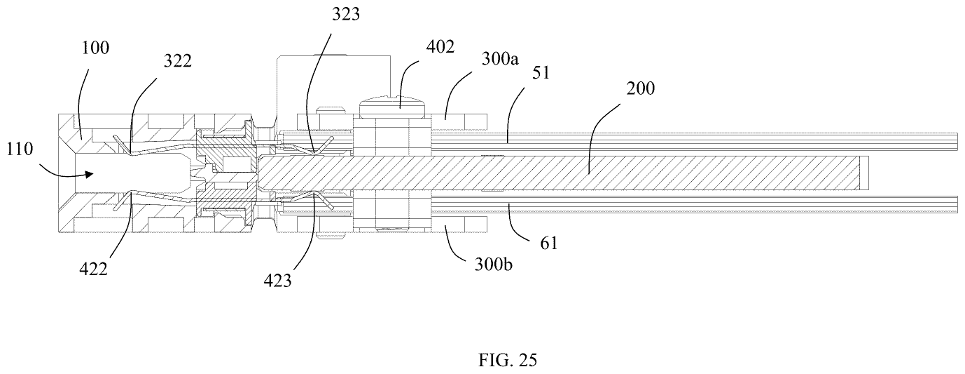

As shown in FIG. 14 and FIG. 15, the circuit board 200 includes a first surface 201 (for example, an upper surface), a second surface 202 (for example, a lower surface) opposite to the first surface 201, a plurality of first conductive pads 203 exposed to the first surface 201, and a plurality of second conductive pads 204 exposed to the second surface 202. In the illustrated embodiment of the present disclosure, the plurality of first conductive pads 203 and the plurality of second conductive pads 204 are disposed along the second direction A2-A2. In the illustrated embodiment of the present disclosure, a plurality of notches 205 are provided at a front end of the circuit board 200. The notches 205 match corresponding extending protrusions 13. The front end of the circuit board 200 is at least partially inserted into the body portion 1. The circuit board 200 is clamped between the first tail portions 323 of the first board-end terminals 32 and the second tail portions 423 of the second board-end terminals 42 (as shown in FIG. 25). The circuit board 200 further includes a plurality of mounting through holes 206 corresponding to the mounting holes 121. The fastening device 400 includes a plurality of fastening components 401 of which each passes through the mounting hole 121 and the mounting through hole 206 to secure the body portion 1 and the circuit board 200 together. In the illustrated embodiment of the present disclosure, the fastening component 401 is a fastening screw.

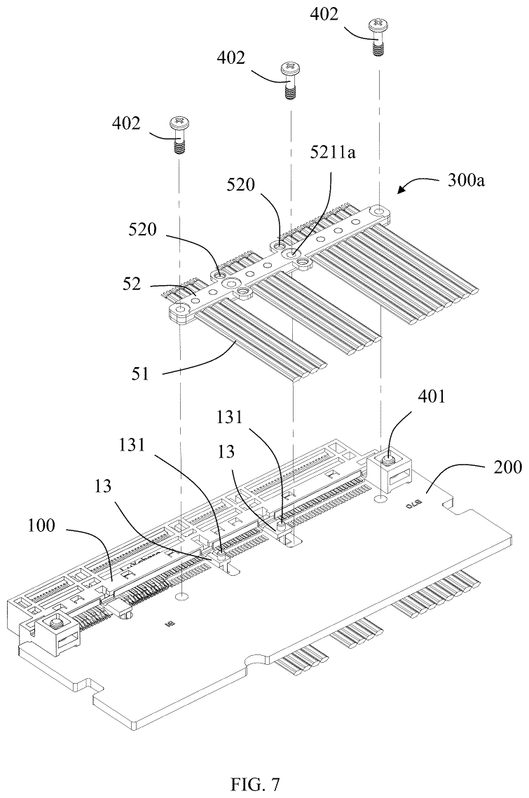

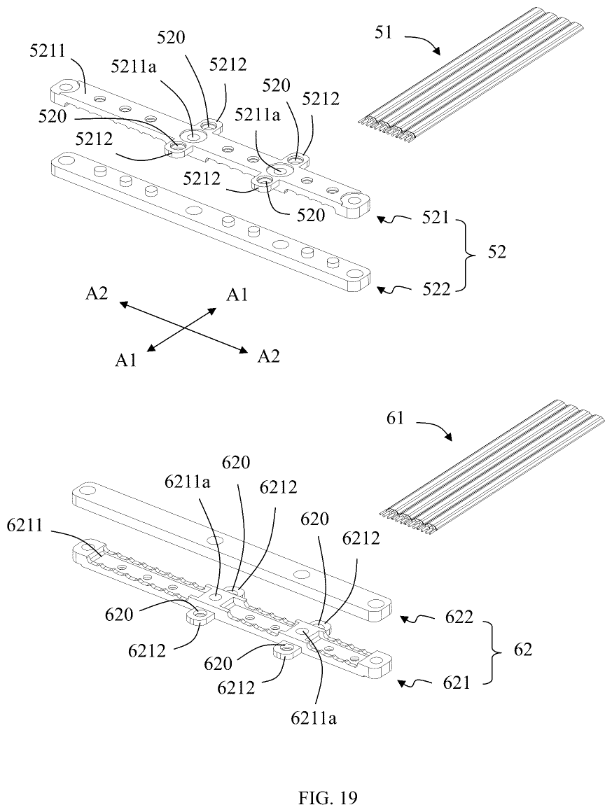

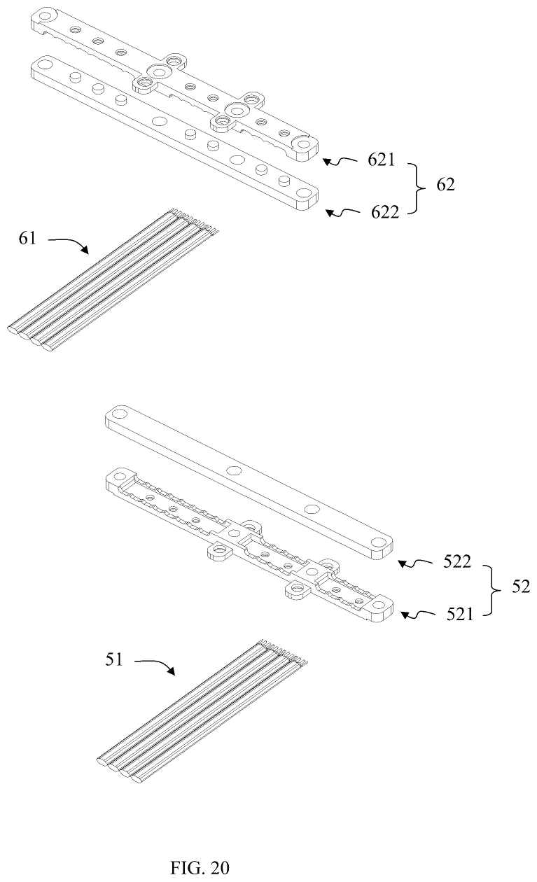

Referring to FIG. 7 to FIG. 13, FIG. 19 and FIG. 20, in the illustrated embodiment of the present disclosure, the cable module 300 includes a first cable module 300a and a second cable module 300b. The first cable module 300a and the second cable module 300b are disposed on opposite sides (for example, upper and lower sides) of the circuit board 200, respectively. That is, the first cable module 300a and the second cable module 300b are provided on the first surface 201 and the second surface 202 of the circuit board 200, respectively.

As shown in FIG. 19 and FIG. 20, the first cable module 300a is formed as a whole, which includes a plurality of first cables 51 and a first fixing block 52 fixing the plurality of first cables 51. In the illustrated embodiment of the present disclosure, the plurality of first cables 51 are disposed along the second direction A2-A2. In a first embodiment of the disclosure, the first fixing block 52 includes a first clamping plate 521 and a second clamping plate 522. The plurality of first cables 51 are clamped between the first clamping plate 521 and the second clamping plate 522. The first clamping plate 521 and the second clamping plate 522 are fixed together. In the illustrated embodiment of the present disclosure, the first clamping plate 521 and the second clamping plate 522 are integrated with the plurality of first cables 51 through heat fusion.

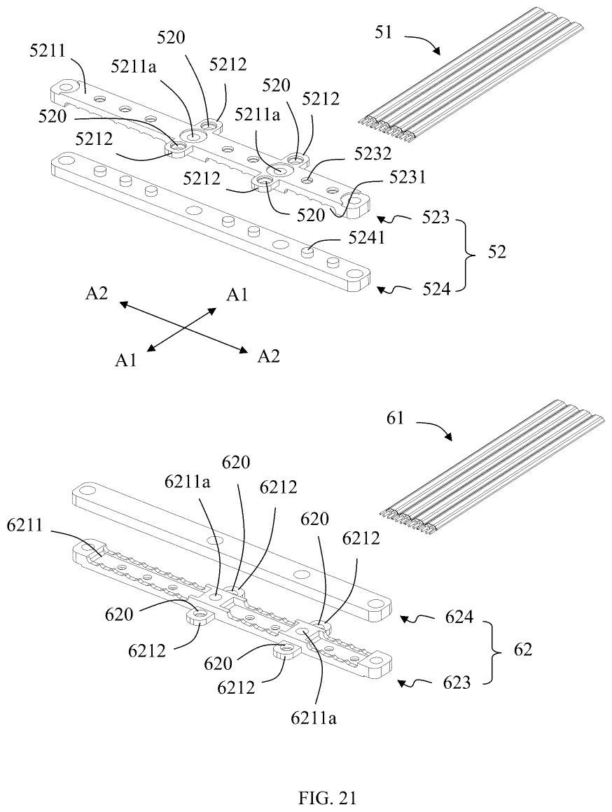

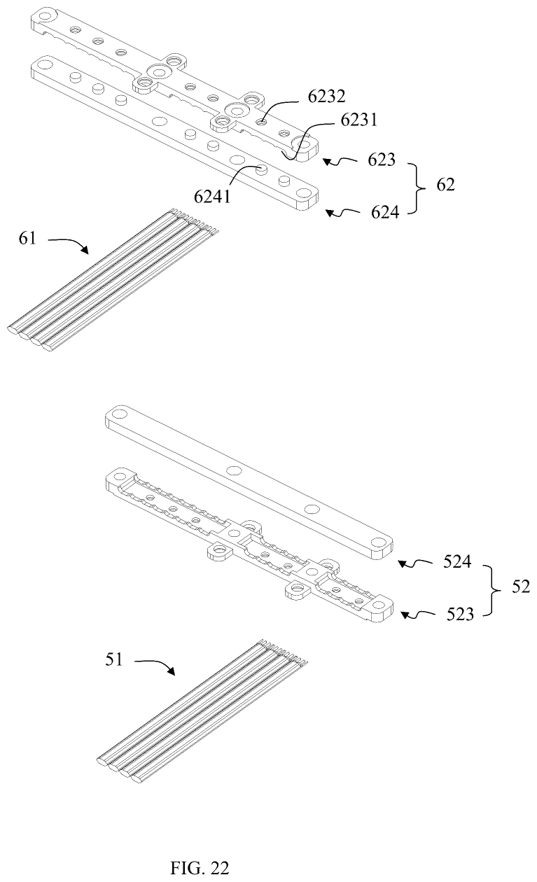

Referring to FIG. 21 and FIG. 22, in a second embodiment of the present disclosure, the first fixing block 52 is at least partially injection molded on the first cables 51, so that the first fixing block 52 and the first cables 51 is integrated as a whole. Specifically, the first fixing block 52 includes a first positioning plate 523 and a first combination block 524. The first positioning plate 523 defines a plurality of first cable grooves 5231 and a plurality of first injection holes 5232. When forming the first cable module 300a, the first cables 51 are firstly positioned in corresponding first cable grooves 5231. Then, material is injected into the first injection holes 5232 to form the first combination block 524. After the injection molding is completed, the first combination block 524 and the first positioning plate 523 are integrated to form the first fixing block 52. Besides, the plurality of first cables 51 and the first fixing block 52 are integrated as a whole. The first combination block 524 includes a plurality of first fixing posts 5241 fixed in the first injection holes 5232 so as to increase the binding force between the first combination block 524 and the first positioning plate 523.

Of course, it is understandable to those skilled in the art that the first cables 51 and the first fixing block 52 can be fixed in various ways. For example, the first fixing block 52 can be fixed with the plurality of first cables 51 by assembly and clamping, which will not be described again in the present disclosure.

The first cable 51 includes a first core 511 electrically connected to the first mounting portion 313 of a corresponding first cable terminal 31, a first insulation layer 512 wrapped on the first core 511, a first ground wire 513 located outside the first insulation layer 512 and an outermost first insulation sheath 514. The first ground wire 513 is connected to the first ground terminal. In the illustrated embodiment of the present disclosure, the first cables 51 are located above the circuit board 200 and is spaced a certain distance away from the circuit board 200.

Similarly, the second cable module 300b is formed as a whole, which includes a plurality of second cables 61 and a second fixing block 62 fixing the plurality of second cables 61. In the illustrated embodiment of the present disclosure, the plurality of second cables 61 are disposed along the second direction A2-A2. In the illustrated embodiment of the present disclosure, the second fixing block 62 includes a third clamping plate 621 and a fourth clamping plate 622. The plurality of second cables 61 are clamped between the third clamping plate 621 and the fourth clamping plate 622. The third clamping plate 621 and the fourth clamping plate 622 are fixed together. In the illustrated embodiment of the present disclosure, the third clamping plate 621 and the fourth clamping plate 622 are integrated with the plurality of second cables 61 through heat fusion. In the illustrated embodiment of the present disclosure, the first clamping plate 521 and the third clamping plate 621 have the same structure, so that parts can be shared and costs can be saved.

Referring to FIG. 21 and FIG. 22, in a second embodiment of the disclosure, the second fixing block 62 is at least partially injection molded on the plurality of second cables 61. The second fixing block 62 and the plurality of second cables 61 are integrated as a whole. Specifically, the second fixing block 62 includes a second positioning plate 623 and a second combination block 624. The second positioning plate 623 defines a plurality of second cable grooves 6231 and a plurality of second injection holes 6232. When forming the second cable module 300b, the second cables 61 are firstly positioned in the corresponding second cable grooves 6231. Then, material is injected into the second injection holes 6232 to form the second combination block 624. After the injection molding is completed, the second combination block 624 and the second positioning plate 623 are integrated as a whole to form the second fixing block 62. Besides, the plurality of second cables 61 and the second fixing block 62 are integrated as a whole. The second combination block 624 includes a plurality of second fixing posts 6241 fixed in the second injection holes 6232 to increase the binding force between the second combination block 624 and the second positioning plate 623. In the illustrated embodiment of the present disclosure, the first positioning plate 523 and the second positioning plate 623 have the same structure, so that parts can be shared and costs can be saved.

Of course, it is understandable to those skilled in the art that the second cables 61 and the second fixing block 62 can be fixed in various ways. For example, the second fixing block 62 can be fixed with the plurality of second cables 61 by assembly and clamping, which will not be described again in the present disclosure.

The second cable 61 includes a second core 611 electrically connected to the second mounting portion 413 of a corresponding second cable terminal 41, a second insulation layer 612 wrapped on the second core 611, a second ground wire 613 located outside the second insulation layer 612, and an outermost second insulation sheath 614. The second ground wire 613 is connected to the second ground terminal. In the illustrated embodiment of the present disclosure, the second cables 61 are located below the circuit board 200 and is spaced a certain distance away from the circuit board 200.

Besides, the body portion 1 and the cable module 300 are also provided with positioning structures that cooperate with each other.

One of the body portion 1 and the first fixing block 52 is provided with a first positioning post 131, and a remaining one of the body portion 1 and the first fixing block 52 is provided with a first positioning hole 520. The first positioning post 131 is at least partially inserted into the first positioning hole 520. In the illustrated embodiment of the present disclosure, the first positioning post 131 is provided on the extending protrusion 13. The first positioning hole 520 is provided on the first fixing block 52. More specifically, in the illustrated embodiment of the present disclosure, the first clamping plate 521/the first positioning plate 523 is provided with a first strip portion 5211 extending along the second direction A2-A2 and a plurality of first protruding portions 5212 protruding from the first strip portion 5211 on both front and rear sides along the first direction A1-A1. The first strip portion 5211 defines a plurality of first mounting through holes 5211a. In the illustrated embodiment of the present disclosure, two first protruding portions 5212 are provided, and each first protruding portion 5212 defines two first positioning holes 520. In the illustrated embodiment of the present disclosure, the two first positioning holes 520 located on the same first protruding portion 5212 and the first mounting through hole 5211a located between the two first positioning holes 520 are aligned and disposed along the first direction A1-A1.

Besides, one of the body portion 1 and the second fixing block 62 is provided with a second positioning post 132, and a remaining one of the body portion 1 and the second fixing block 62 is provided with a second positioning hole 620. The second positioning post 132 is at least partially inserted into the second positioning hole 620. In the illustrated embodiment of the present disclosure, the second positioning post 132 is provided on the extending protrusion 13. The second positioning hole 620 is provided on the second fixing block 62. More specifically, in the illustrated embodiment of the present disclosure, the third clamping plate 621/the second positioning plate 623 is provided with a second strip portion 6211 extending along the second direction A2-A2 and a plurality of second protruding portions 6212 protruding from the second strip portion 6211 on both front and rear sides along the first direction A1-A1. The second strip portion 6211 defines a plurality of second mounting through holes 6211a. In the illustrated embodiment of the present disclosure, two second protrusions 6212 are provided, and each second protrusion 6212 defines two second positioning holes 620. In the illustrated embodiment of the present disclosure, the two second positioning holes 620 located on the same second protruding portion 6212 and the second mounting through hole 6211a located between the two second positioning holes 620 are aligned and disposed along the first direction A1-A1.

In the illustrated embodiment of the present disclosure, the first cable module 300a and the second cable module 300b have the same structure and different installation angles, so that parts can be shared and costs can be saved.

The present disclosure further discloses a method of manufacturing the cable connector assembly, which includes:
providing the electrical connector 100;
providing the circuit board 200, and assembling the electrical connector 100 and the circuit board 200 together;
providing a cable module 300, the cable module 300 including a plurality of cables and a fixing block fixing the plurality of cables, the cable including a core; and
securing the fixing block to the circuit board 200 so that the core of the cable corresponds to the mounting portion of a corresponding conductive terminal 2; the core of the cable being electrically connected to the mounting portion of the corresponding conductive terminal 2.

In an embodiment of the present disclosure, forming the cable module 300 includes:
providing the plurality of cables;
providing a positioning plate, the positioning plate defining a plurality of cable grooves in which the plurality of cables are positioned;
injection molding a combination block, the combination block and the positioning plate being integrated as a whole to form the fixing block; and the plurality of cables and the fixing block being integrated as a whole.

The positioning plate defines a plurality of injection holes. The combination block is formed by injecting material into the injection holes. The combination block includes a plurality of fixing posts fixed in the injection holes.

Specifically, in the illustrated embodiment of the present disclosure, after the electrical connector 100 and the circuit board 200 are assembled, the first tail portions 323 of the first board-end terminals 32 and the second tail portions 423 of the second board-end terminals 42 are in contact with the first conductive pads 203 and the second conductive pads 204 of the circuit board 200, respectively. Of course, in order to improve contact reliability, the first tail portions 323 of the first board-end terminals 32 and the second tail portions 423 of the second board-end terminals 42 are fixed to the first conductive pads 203 and the second conductive pads 203 of the circuit board 200, respectively, by soldering or welding.

In the illustrated embodiment of the present disclosure, the cable module 300 includes the first cable module 300a and the second cable module 300b. The first cable module 300a and the second cable module 300b are integrally assembled on opposite sides of the electrical connector 100, respectively. After the assembly is completed, the first cable module 300a and the second cable module 300b are located on the opposite sides (for example, upper and lower sides) of the circuit board 200, respectively. At this time, the first core 511 of the first cable 51 corresponds to the first mounting portion 313 of the corresponding first cable terminal 31; and the second core 611 of the second cable 61 corresponds to the second mounting portion 413 of the corresponding second cable terminal 41.

The first core 511 of the first cable 51 is electrically connected to the first mounting portion 313 of the corresponding first cable terminal 31. The second core 611 of the second cable 61 is electrically connected to the second mounting portion 413 of the corresponding second cable terminal 41. In one embodiment of the present disclosure, the first core 511 of the first cable 51 is fixed to the first mounting portion 313 of the corresponding first cable terminal 31 by soldering or welding. The second core 611 of the second cable 61 is fixed to the second mounting portion 413 of the corresponding second cable terminal 41 by soldering or welding.

The fastening device 400 further includes a plurality of fasteners 402 for securing the fixing block to the circuit board 200. In the illustrated embodiment of the present disclosure, the fastener 402 includes a screw. The fastener 402 passes through the first mounting through hole 5211a, the circuit board 200 and the second mounting through hole 6211a, so as to secure the first cable module 300a, the circuit board 200 and the second cable module 300b together.

It is understandable to those skilled in the art that in the present disclosure, the first cable module 300a and the second cable module 300b are respectively configured as an integral structure. Through integral installation, the first core 511 of the first cable 51 can correspond to the first mounting portion 313 of the corresponding first cable terminal 31, and the second core 611 of the second cable 61 can correspond to the second mounting portion 413 of the corresponding second cable terminal 41. Besides, the first cable module 300a, the circuit board 200 and the second cable module 300b are fixed together through the fasteners 402, the fixation of the first fixing block 52 to the circuit board 200 can protect the soldering or welding portion of the first core 511 of the first cable 51 and the first mounting portion 313 of the corresponding first cable terminal 31. The fixation of the second fixing block 62 to the circuit board 200 can protect the soldering or welding portion of the second core 611 of the second cable 61 and the second mounting portion 413 of the corresponding second cable terminal 41, thereby preventing the soldering or welding portions fail due to external force pulling.

It should be noted that in the description of the present disclosure, the terms “first”, “second”, “third”, “fourth”, etc., are only used to distinguish the naming of components and have no other implicit order or logical relationship. For example, a general concept of the first cable terminal 31, the first board-end terminal 32, the second cable terminal 41 and the second board-end terminal 42 is the conductive terminal 2; a general concept of the first contact portion 312, the first mating portion 322, the second contact portion 412 and the second mating portion 422 is a contact portion; a general concept of the first mounting part 313 and the second mounting part 413 is a mounting part; a general concept of the first cable module 300a and the second cable module 300b is the cable module 300; a general concept of the first cable 51 and the second cable 61 is the cable; a general concept of the first core 511 and the second core 611 is the core; a general concept of the first fixing block 52 and the second fixing block 62 is the fixing block, so on and so forth.

The above embodiments are only used to illustrate the present disclosure and not to limit the technical solutions described in the present disclosure. The understanding of this specification should be based on those skilled in the art. Descriptions of directions, although they have been described in detail in the above-mentioned embodiments of the present disclosure, those skilled in the art should understand that modifications or equivalent substitutions can still be made to the application, and all technical solutions and improvements that do not depart from the spirit and scope of the application should be covered by the claims of the application.

What is claimed is:

1. A cable connector assembly, comprising:
an electrical connector, the electrical connector comprising a body portion and a plurality of conductive terminals provided on the body portion; at least part of the conductive terminals comprising a contact portion and a mounting portion; the contact portion being configured to be in contact with a mating module;
a circuit board, the electrical connector and the circuit board being mounted together; and
a cable module, the cable module comprising a plurality of cables and a fixing block fixing the plurality of cables; the cable comprising a core; the fixing block being secured to the circuit board so that the core of the cable corresponds to the mounting portion of a corresponding conductive terminal; the core of the cable being electrically connected to the mounting portion of the corresponding conductive terminal.

2. The cable connector assembly according to claim 1, further comprising a fastener that secure the fixing block to the circuit board.

3. The cable connector assembly according to claim 2, wherein the fastener comprises a screw.

4. The cable connector assembly according to claim 1, wherein one of the body portion and the fixing block is provided with a positioning post, a remaining one of the body portion and the fixing block is provided with a positioning hole, and the positioning post is at least partially inserted in the positioning hole.

5. The cable connector assembly according to claim 1, wherein the circuit board comprises a first surface and a plurality of first conductive pads exposed on the first surface;
the plurality of conductive terminals comprise a plurality of first cable terminals and a plurality of first board-end terminals; each first cable terminal comprises a first contact portion and a first mounting portion; each first board-end terminal comprises a first mating portion and a first tail portion; the first tail portion is in contact with a corresponding first conductive pad; the contact portion comprises the first contact portion and the first mating portion; the mounting portion comprises the first mounting portion;
the cable module comprises a first cable module; the first cable module comprises a plurality of first cables and a first fixing block fixing the plurality of first cables; the plurality of cables comprise the plurality of first cables, and the fixing block comprises the first fixing block;
each first cable comprises a first core electrically connected to the first mounting portion of a corresponding first cable terminal; the first fixing block is secured to the circuit board so that the first core of the first cable corresponds to the first mounting portion of the corresponding first cable terminal; the first core of the first cable is electrically connected to the first mounting portion of the corresponding first cable terminal.

6. The cable connector assembly according to claim 5, wherein the circuit board comprises a second surface opposite to the first surface and a plurality of second conductive pads exposed to the second surface;
the plurality of conductive terminals comprise a plurality of second cable terminals and a plurality of second board-end terminals; each second cable terminal comprises a second contact portion and a second mounting portion; each second board-end terminal comprises a second mating portion and a second tail portion; the second tail portion is in contact with a corresponding second conductive pad; the contact portion comprises the second contact portion and the second mating portion; the mounting portion comprises the second mounting portion;
the cable module comprises a second cable module; the second cable module comprises a plurality of second cables and a second fixing block fixing the plurality of second cables; the plurality of cables comprises the plurality of second cables; the fixing block comprises the second fixing block;
the second cable comprises a second core electrically connected to the second mounting portion of a corresponding second cable terminal; the second fixing block is secured to the circuit board so that the second core of the second cable corresponds to the second mounting portion of the corresponding second cable terminal; the second core of the second cable is electrically connected to the second mounting portion of the corresponding second cable terminal.

7. The cable connector assembly according to claim 6, wherein the first cable module and the second cable module are located on opposite sides of the circuit board, respectively;
the first tail portion of the first board-end terminal and the second tail portion of the second board-end terminal are both cantilever-shaped and elastic; the circuit board is clamped between the first tail portion of the first board-end terminal and the second tail portion of the second board-end terminal.

8. The cable connector assembly according to claim 6, wherein the first cable module and the second cable module are located on opposite sides of the circuit board, respectively;
the cable connector assembly comprises a fastener that secures the first fixing block, the circuit board and the second fixing block together.

9. The cable connector assembly according to claim 6, wherein the first fixing block is at least partially injection molded on the plurality of first cables;
the second fixing block is at least partially injection molded on the plurality of second cables.

10. The cable connector assembly according to claim 1, wherein the body portion comprises a mating surface and a mating slot extending through the mating surface; the contact portion is arc-shaped and protrudes into the mating slot.

11. The cable connector assembly according to claim 1, wherein the body portion comprises a mounting protrusion and a mounting hole extending through the mounting portion;
the circuit board defines a mounting through hole corresponding to the mounting hole;
the cable connector assembly comprises a fixing component passing through the mounting hole and the mounting through hole to secure the body portion and the circuit board together.

12. A method of manufacturing a cable connector assembly, the cable connector assembly comprising:
an electrical connector, the electrical connector comprising a body portion and a plurality of conductive terminals provided on the body portion; at least part of the conductive terminals comprising a contact portion and a mounting portion; the contact portion being configured to be in contact with a mating module;
a circuit board, the electrical connector and the circuit board being mounted together; and
a cable module, the cable module comprising a plurality of cables and a fixing block fixing the plurality of cables; the cable comprising a core; the fixing block being secured to the circuit board so that the core of the cable corresponds to the mounting portion of a corresponding conductive terminal; the core of the cable being electrically connected to the mounting portion of the corresponding conductive terminal;
the method comprising:
providing the electrical connector;
providing the circuit board, and mounting the electrical connector and the circuit board together;
providing the cable module, and securing the fixing block to the circuit board so that the core of the cable corresponds to the mounting portion of the corresponding conductive terminal.

13. The method of manufacturing the cable connector assembly according to claim 12, wherein forming the cable module comprises:
providing the plurality of cables;
providing a positioning plate, the positioning plate defining a plurality of cable grooves in which the plurality of cables are positioned; and
injection molding a combination block, the combination block and the positioning plate being integral to form the fixing block, and the plurality of cables and the fixing block being integrally formed.

14. The method of manufacturing the cable connector assembly according to claim 13, wherein the positioning plate defines an injection hole; the combination block is formed by injecting material into the injection hole; the combination block comprises a fixing post fixed in the injection hole.

15. The method of manufacturing the cable connector assembly according to claim 12, wherein the core of the cable and the mounting portion of the corresponding conductive terminal are electrically connected by soldering or welding.

16. The method of manufacturing the cable connector assembly according to claim 12, further comprising:
providing a fastener to secure the fixing block to the circuit board.

17. The method of manufacturing the cable connector assembly according to claim 12, wherein the circuit board comprises a first surface and a plurality of first conductive pads exposed on the first surface;
the plurality of conductive terminals comprise a plurality of first cable terminals and a plurality of first board-end terminals; each first cable terminal comprises a first contact portion and a first mounting portion; each first board-end terminal comprises a first mating portion and a first tail portion; the first tail portion is in contact with a corresponding first conductive pad; the contact portion comprises the first contact portion and the first mating portion; the mounting portion comprises the first mounting portion;
the cable module comprises a first cable module; the first cable module comprises a plurality of first cables and a first fixing block fixing the plurality of first cables; the plurality of cables comprise the plurality of first cables, and the fixing block comprises the first fixing block;
each first cable comprises a first core electrically connected to the first mounting portion of a corresponding first cable terminal; the first fixing block is secured to the circuit board so that the first core of the first cable corresponds to the first mounting portion of the corresponding first cable terminal; the first core of the first cable is electrically connected to the first mounting portion of the corresponding first cable terminal.

18. The method of manufacturing the cable connector assembly according to claim 17, wherein the circuit board comprises a second surface opposite to the first surface and a plurality of second conductive pads exposed to the second surface;
the plurality of conductive terminals comprise a plurality of second cable terminals and a plurality of second board-end terminals; each second cable terminal comprises a second contact portion and a second mounting portion; each second board-end terminal comprises a second mating portion and a second tail portion; the second tail portion is in contact with a corresponding second conductive pad; the contact portion comprises the second contact portion and the second mating portion; the mounting portion comprises the second mounting portion;
the cable module comprises a second cable module; the second cable module comprises a plurality of second cables and a second fixing block fixing the plurality of second cables; the plurality of cables comprises the plurality of second cables; the fixing block comprises the second fixing block;
the second cable comprises a second core electrically connected to the second mounting portion of a corresponding second cable terminal; the second fixing block is secured to the circuit board so that the second core of the second cable corresponds to the second mounting portion of the corresponding second cable terminal; the second core of the second cable is electrically connected to the second mounting portion of the corresponding second cable terminal.

19. The method of manufacturing the cable connector assembly according to claim 18, wherein the first cable module and the second cable module are located on opposite sides of the circuit board, respectively;
the first tail portion of the first board-end terminal and the second tail portion of the second board-end terminal are both cantilever-shaped and elastic; the circuit board is clamped between the first tail portion of the first board-end terminal and the second tail portion of the second board-end terminal.

20. The method of manufacturing the cable connector assembly according to claim 18, wherein the first fixing block is at least partially injection molded on the plurality of first cables;
the second fixing block is at least partially injection molded on the plurality of second cables.
